(19) United States
(12) Patent Application Publication
(10) Pub. No.: US 2017/0213581 A1
(43) Pub. Date: Jul. 27, 2017

(54) PROCESSING UNIT, IN-MEMORY DATA PROCESSING APPARATUS AND METHOD

(71) Applicant: ELECTRONICS AND TELECOMMUNICATIONS RESEARCH INSTITUTE, Daejeon (KR)

(72) Inventors: Young-Woo KIM, Daejeon (KR); Myeong-Hoon OH, Daejeon (KR)

(21) Appl. No.: 15/198,555

(22) Filed: Jun. 30, 2016

(30) Foreign Application Priority Data
Jan. 27, 2016 (KR) 10-2016-0010215

(51) Int. Cl. G11C 7/10

(52) U.S. Cl. CPC G11C 7/106; G11C 7/1072

(57) ABSTRACT

A processing unit, and an in-memory data processing apparatus. The in-memory data processing apparatus includes a memory storing data at a determined location, a plurality of selector units selecting a data set to be used for an operation from among the stored data, and a plurality of processing units performing the operation using an instruction set sequentially received from an outside and the selected data set.

### CROSS REFERENCE TO RELATED APPLICATION

This application claims the benefit of Korean Patent Application No. 10-2016-0010215, filed Jan. 27, 2016, which is hereby incorporated by reference in its entirety into this application.

### BACKGROUND OF THE INVENTION

1. Technical Field

The present invention relates generally to a data-driven apparatus and method for in-memory data processing, and, more particularly, to a technique for fixing a data location in a memory device and processing data while moving an operation instruction executed in a processing unit connected to the memory device.

2. Description of the Related Art

A computer system mainly uses a high-speed processor in order to process data, and nowadays, with the development of a semiconductor process, a processor is capable of processing data at high speed.

However, data provided to a processor for processing is stored in external memory, the operation speed of which is relatively low compared to the processor, and accordingly, a limitation whereby data processing is delayed in the processor may occur. In order to address such a limitation, a cache is embedded inside the processor to compensate for the low speed of external memory.

Recently, in response to increases in the absolute amount of data to be processed, a multi-layer cache architecture has been adopted to compensate for decreased speed due to frequent data loading. In addition, a processing-in-memory (PIM) architecture for processing data in memory is actively being researched.

In the existing processor architecture and the recent PIM architecture, a method for moving data to a processing unit, which processes data, is fundamentally used for processing data. However, in this related art, there may be a limitation due to the difference between the data processing speed and the data moving speed or due to a difference between the energy required to move data and the energy required to process data.

With the development of semiconductor technology, the data processing speed for a single instruction has become very fast. However, when data is moved to a processing unit which processes data in the manner of an execution unit in a processor, a relatively long time is taken, and accordingly the data processing speed becomes lower.

For example, a processor operating at 1 GHz takes 1 ns to process one instruction. However, the action of accessing data in memory outside the processor through a bus takes tens of ns. That is, in the worst case, data processing performance may be lowered due to the memory access speed.

In addition, like a big data application, an application for processing large amounts of data is required to move data to a processor in which the data is processed. This action consumes tens of times to hundreds of times the amount of energy consumed to perform a single instruction.

For example, energy of 0.64 nJ is consumed for processing one ADD instruction, but energy of 63.64 nJ is required to move data from external memory to an internal register.

Accordingly, in typical data processing, technical development is urgently required to address a limitation related to performance degradation and a limitation related to the use of large amounts of energy due to a method for moving data from external memory to a processing unit through a memory controller and a bus.

### CITATION LIST

### Patent Literature

(Patent Literature 1) Korean Patent Application No. 10-2002-7008455, published on Sep. 13, 2002 (Title: Method and apparatus for processing input information unit and data packet processing apparatus)

### SUMMARY OF THE INVENTION

Accordingly, the present invention has been made keeping in mind the above problems occurring in the prior art, and an object of the present invention is to provide an apparatus and method for in-memory data processing which may address a time delay limitation attributable to movement of data stored in external memory to a processing unit through a bus, and may prevent a performance degradation caused by the time delay, thereby enabling data to be processed at a high speed.

Another object of the present invention is to provide an apparatus and method for in-memory data processing which may reduce unnecessary energy consumption for data processing and may accordingly enable the processing of large amounts of data with small power consumption.

In accordance with an aspect of the present invention for accomplishing the above object, there is provided an in-memory data processing apparatus including: a memory for storing data at a determined location; a plurality of selector units for selecting a data set to be used for an operation from among the stored data; and a plurality of processing units for performing the operation using an instruction set sequentially received from an outside and the selected data set.

The plurality of processing units may be mutually connected in a multi-dimensional array.

The data stored in the memory may be directly connected to each of the processing units through at least one of the processing units and the selector units.

The number of selector units may correspond to the number of the plurality of processing units, and the plurality of selector units may be mutually connected in a multi-dimensional array.

The processing units may be paired with respective selector units for selecting data to be processed by the processing units.

Each of the selector units may allow each processing unit paired therewith to combine and form a pair with data stored at a specific location in memory.

The processing unit and data pairs may be connected in series so as to be operated by each of the processing units.

An input to the processing unit may be received from a preceding adjacent processing unit and may include a previous instruction and a previous processing result, which are an operation to be performed by the corresponding processing unit and an instruction designating data, as well as the data received from the selector unit corresponding to the processing unit.

The output of the processing unit may be an instruction that is received and performed by the processing unit and a processing result corresponding to the instruction.

The processing units may use a common clock or a synchronous handshaking scheme so as to deliver the instruction and the processing result, which are output from the processing unit, to the subsequent adjacent processing unit.

The processing unit may output a data selection signal for requesting the selection of data to be used for the operation to the selector unit corresponding to the processing unit, and the selector unit may select some data from among the data set corresponding to the processing unit and may transmit the selected data to the processing unit.

The instruction set may be sequentially applied to the processing unit, and the instructions included in the instruction set may be configured with one or more operator fields, a plurality of operand fields, and one or more operation result fields.

In accordance with an aspect of the present invention for accomplishing the above object, there is provided a processing unit that includes: an instruction decoder for decoding an instruction including an operation to be performed and data used for the operation, and generating a control signal; an internal execution unit for operating the data so as to correspond to the instruction; an input result selector for determining whether to use a processing result of a preceding processing unit, which has been input, using the control signal; and an output selector for selecting the subsequent processing unit, to which the instruction and the processing result corresponding to the instruction are to be delivered.

The instruction decoder may decode an instruction set sequentially received from the outside or a previous instruction received from the preceding processing unit adjacent thereto.

The internal execution unit may output the instruction that is being performed by the processing unit and the processing result corresponding to the instruction.

The instruction set may be configured with one or more operator fields, a plurality of operand fields, and one or more operation result fields.

The operator field may indicate the type of operation to be executed by the internal execution unit, the operand field may indicate the data necessary for an operation, among a data set, and the operation result field may indicate whether the processing unit performs an operation using the operation result of the preceding processing unit or whether to deliver the operation result of the processing unit to the subsequent processing unit.

The processing unit may be embedded in a memory device in which the data is stored.

In accordance with an aspect of the present invention for accomplishing the above object, there is provided a data processing method performed by an in-memory data processing apparatus, the data processing method including: sequentially receiving an instruction set from an outside; selecting, by a selector unit, a data set to be used for an operation corresponding to the instruction set from memory in which data is stored at a determined location; and performing an operation corresponding to the instruction set and the data set using a plurality of processing units.

The plurality of processing units may be mutually connected in a multi-dimensional array.

The data processing method may further include delivering instructions included in the instruction set to a subsequent adjacent processing unit.

### BRIEF DESCRIPTION OF THE DRAWINGS

The above and other objects, features and advantages of the present invention will be more clearly understood from the following detailed description taken in conjunction with the accompanying drawings, in which:

FIG. 1 illustrates a processor structure for a computer operation process according to a related art;

FIG. 2 is a block diagram of a configuration of an in-memory data processing apparatus according to an embodiment of the present invention;

FIG. 3 is a drawing for explaining an in-memory data processing structure according to an embodiment of the present invention;

FIG. 4 is a drawing for explaining instruction delivery and a data processing flow of a processing unit according to an embodiment of the present invention;

FIG. 5 is an exemplary diagram illustrating the hardware logic structure of an in-memory data processing apparatus according to an embodiment of the present invention;

FIG. 6 is an exemplary diagram illustrating the physical structure of an in-memory data processing apparatus according to an embodiment of the present invention;

FIG. 7 is a drawing for explaining a processing unit structure according to an embodiment of the present invention;

FIG. 8 is a drawing for explaining a selector unit structure according to an embodiment of the present invention; and

FIG. 9 is a drawing for explaining an instruction set structure according to an embodiment of the present invention.

### DESCRIPTION OF THE PREFERRED EMBODIMENTS

The present invention will be described in detail below with reference to the accompanying drawings. Repeated descriptions and descriptions of known functions and configurations which have been deemed to make the gist of the present invention unnecessarily obscure will be omitted below. The embodiments of the present invention are intended to fully describe the present invention to a person having ordinary knowledge in the art to which the present invention pertains. Accordingly, the shapes, sizes, etc. of components in the drawings may be exaggerated to make the description clearer.

Hereinafter, embodiments of the present invention will be described in detail with reference to the accompanying drawings.

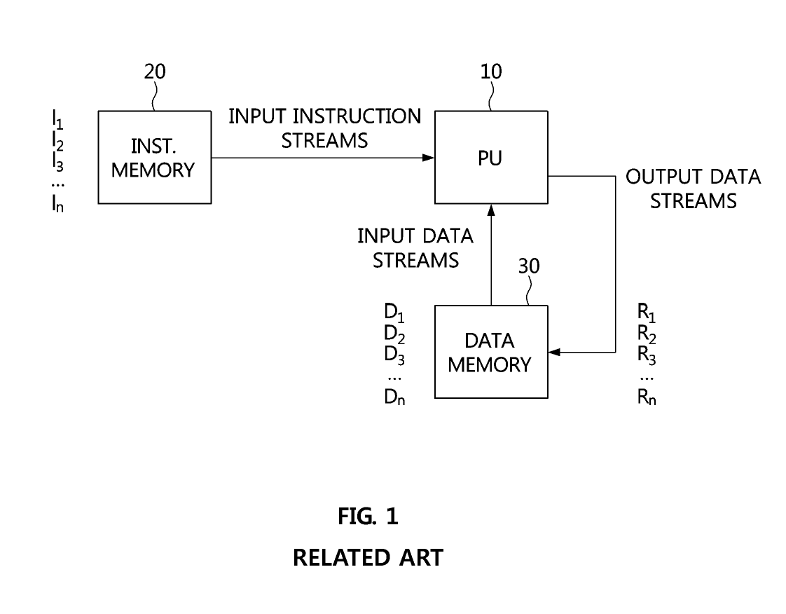

FIG. 1 illustrates a processor structure for a computer operation process according to a related art.

As illustrated in FIG. 1, a typical processing unit (PU) 10, which means a microprocessor, reads a plurality of data sets (D₁, D₂, D₃, . . . , D_{N}) from a data memory 30 through a memory controller outside the PU 10 and a data bus according to a sequence of instructions (I₁, I₂, I₃, . . . , Iₙ) sequentially provided from an instruction memory 20 through the memory controller outside the PU 10 and an instruction bus.

In addition, the PU 10 processes an instruction at a corresponding time when a data set is read, and stores, in the data memory 30, the read result (R₁, R₂, R₃, . . . , R_{N}) through the memory controller outside the PU 10 and the data bus.

For example, when trying to perform addition ten times, 10 addition instructions and 20 data items are required. In each addition operation, two data items are read from the data memory 30, which is external memory, through a data bus, and an operation process is repeated 10 times in the PU 10 according to a time sequence.

At this point, when the speed at which data are read from the data memory 30, which is external memory, through the memory controller and the data bus is lower than a data operation speed in the PU 10, data processing is determined according to memory read performance, and accordingly a performance degradation results. In addition, since a data read from the data memory 30 is frequently performed, a large amount of energy is consumed.

In addition, a typical microprocessor mainly processes data by applying pipeline-based data processing. The typical pipeline-based data processing only performs a single operation function, for which a processing operation type and the function of each PU in a pipeline are fixed.

In other words, a plurality of PUs, which have fixed functions according to a series of operation processes, are connected, and then data processing is performed by sequentially applying data desired to be processed thereto from outside the pipeline.

On the other hand, an in-memory data processing apparatus according to an embodiment of the present invention adopts a data-driven in-memory processing scheme to address a limitation of the typical data processing scheme.

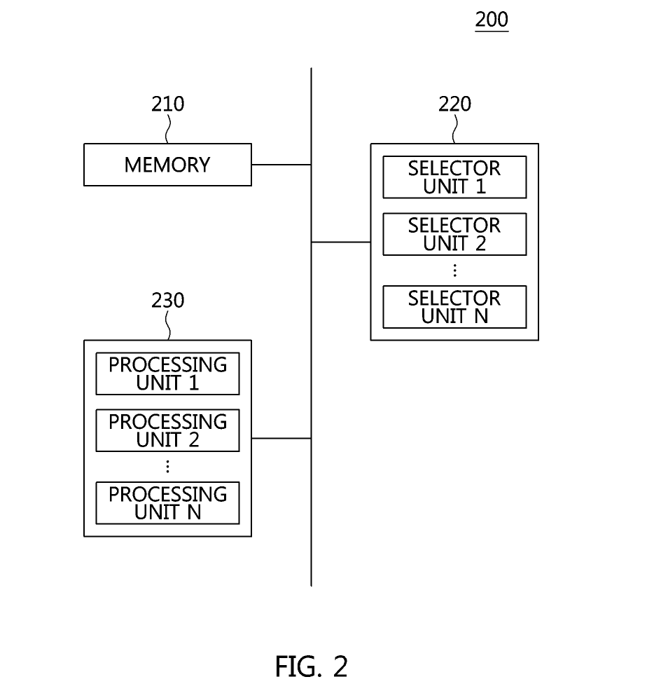

Hereinafter an in-memory data processing apparatus according to embodiments of the present invention will be described in detail with reference to FIGS. 2 to 9.

FIG. 2 is a block diagram of the configuration of an in-memory data processing apparatus according to an embodiment of the present invention.

As illustrated in FIG. 2, an in-memory data processing apparatus 200 includes memory 210, a plurality of selector units 220, and a plurality of PUs 230.

Interconnections between the memory 210, the plurality of selector units 220, and the plurality of PUs 230 configuring the in-memory data processing apparatus 200 of FIG. 2 are not performed in a scheme in which the memory 210 and the PUs 230 are connected through a typical memory controller and a bus based thereon, but have a structure in which individual data bits of the memory 210 are directly connected to the PUs 230 corresponding thereto through the selector units 220.

Firstly, the memory 210 stores data on which operations are to be performed. At this point, the memory 210 stores data at determined locations.

Then the plurality of selector units 220 select, from among the stored data, data sets to be used for operations, which are associated with the PUs 230 corresponding to respective selector units 220 and are directly connected thereto.

At this point, the number of the plurality of selector units 220 corresponds to the number of the plurality of PUs 230 and may be mutually connected in a multi-dimensional array.

Finally, the plurality of PUs 230 perform operations using instruction sets sequentially received and selected from the outside. At this point, the instruction sets are sequentially applied to the plurality of PUs 230 and the instructions included in the instruction set may be configured with one or more operator fields, a plurality of operand fields, and one or more operation result fields. In addition, the plurality of PUs 230 may be mutually connected in a multi-dimensional array.

In addition, the plurality of PUs 230 are respectively paired with the selector units for selecting data to be processed by the corresponding PU. At this point, the selector units 220 allows the PUs 230 respectively paired therewith to combine with data stored at a specific location in the memory 210 to form pairs. In addition, the PU and data pairs are serially connected, and operations are performed on the data by the respective PUs.

In other words, respective PU-selector unit pairs of the PUs and the selector units 220 are paired with respective data at determined locations inside the memory 210 to process the paired data.

The inputs to the plurality of PUs 230 are a previous instruction and a previous processing result received from a preceding PU adjacent to the present PU, and data received from a selector unit corresponding to the present PU.

In other words, the present PU receives an instruction that was executed in a previous time unit by the preceding PU, adjacent to the present PU, and performs an operation corresponding to an instruction in the present time unit. In addition, the PU may also receive a constant, rather than the operation result of the preceding PU.

In addition, outputs of the plurality of PUs 230 are instructions that are received and are being performed by respective present PUs and processing results corresponding to the instructions that are being performed.

In addition, the plurality of PUs 230 may use a common clock or an asynchronous handshaking scheme in order to deliver an instruction and a processing result to the subsequent PU, adjacent to the present PU.

In addition, each PU may output a data selection signal, for requesting the selection of data to be used for an operation, to a selector unit corresponding thereto and may receive, from the selector unit, some data selected from the data set corresponding to the PU.

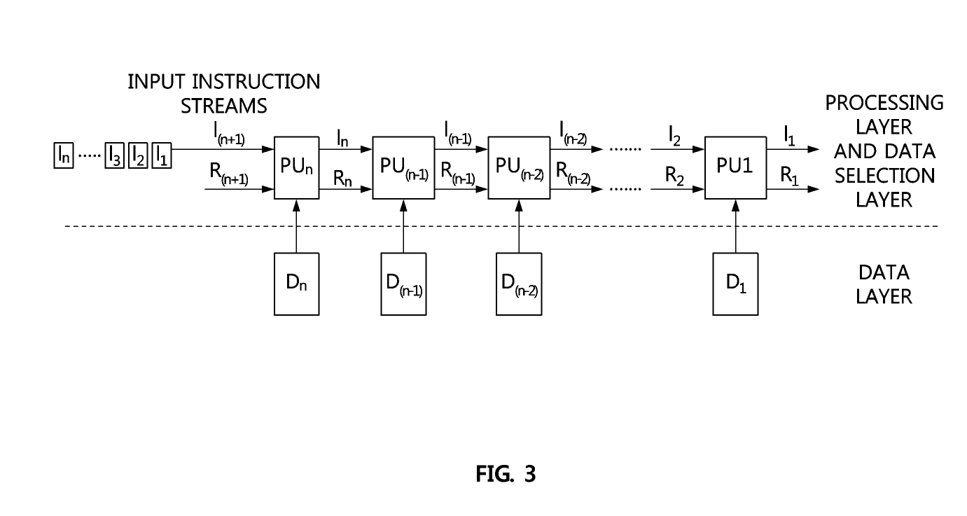

FIG. 3 is a drawing for explaining an in-memory data processing structure according to an embodiment of the present invention.

As illustrated in FIG. 3, an in-memory data processing apparatus according to an embodiment of the present invention does not use a fixed single operation function, but uses an arithmetic logic processing apparatus-based PU capable of processing general purpose operations.

The in-memory data processing apparatus has PUs embedded in a memory device, in which data desired to be used in an operation is located, in order to process a series of instructions. In addition, the in-memory data processing apparatus may be provided with a plurality of PUs corresponding to the size of the data set.

The in-memory data processing apparatus is embedded in the memory device, and a datum in the memory device is paired with a PU corresponding thereto and may be directly connected to a specific PU.

In addition, unlike a typical microprocessor and pipeline device, since data is stored at a determined location in the memory, the in-memory data processing apparatus according to an embodiment of the present invention does not operate according to a scheme whereby data is externally applied, but operates according to a scheme whereby a series of instruction sets is sequentially applied. In addition, in data operation, the in-memory data processing apparatus does not receive data from the outside through the memory controller and data bus, unlike the typical scheme. In addition, operations are performed while each instruction applied from the outside is moved to each PU in the in-memory data processing apparatus.

In addition, each of the PUs receives an instruction I for designating an operation desired to be executed in a corresponding PU and data to be used for the operation, a constant or an operation result R of the previous PU, and a data set D paired with the corresponding PU and existing at a determined location in the memory. In addition, the corresponding PU outputs an instruction I, which was received and executed in a previous time unit, and an operation result R corresponding to the corresponding instruction I.

For data processing, each PU may form a pair PUₙ-Dₙ PAIRS with data desired to be processed. In addition, the PU-data pairs are connected in series and processed as a series of data.

As illustrated in FIG. 3, in order to allow a series of operations to be repeatedly performed on fixed data, each PU sequentially receives a series of operation instructions to be executed from the outside and processes them.

For example, when performing an addition operation 10 times, the data-driven in-memory data processing apparatus, which is configured with the PU-data pairs connected in series, sequentially applies 10 addition instructions to output addition results for 20 data items as a final output of the series connection.

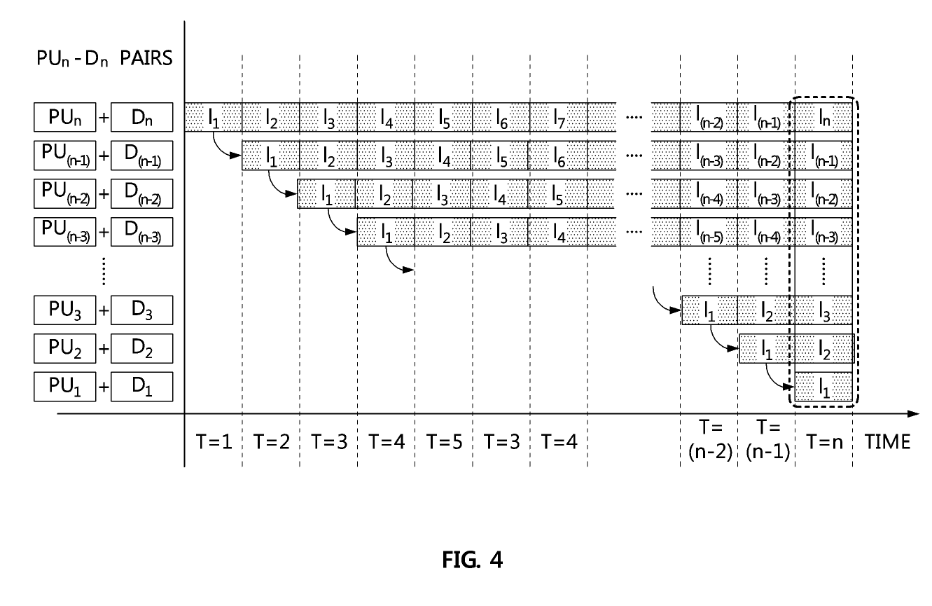

FIG. 4 is a drawing for explaining instruction delivery and a data process flow of a PU according to an embodiment of the present invention.

The PUₙ-Dₙ PAIRS means PU-data pairs for which data processing occurs, and FIG. 4 illustrates a process of operations performed through the application of instructions according to each time unit T.

As illustrated in FIG. 4, when I₁, which is a first instruction, is applied to the PUₙ-Dₙ pair in a time unit at which T=1, the PUₙ-Dₙ pair performs an operation of I₁ and as a result, outputs the instruction I₁ and the operation result R₁.

In addition, in a time unit at which T=2, the PUₙ-Dₙ, pair receives and performs a new instruction I₂, and at the same time, a PU₍ₙ₋₁₎-D₍ₙ₋₁₎ pair performs an operation for data set D₍ₙ₋₁₎ having, as an input, the instruction I₁ and the operation result R₁, which were the output of the PUₙ-Dₙ pair in a previous stage. In this way, the result of all operations is output as the output of the PU₁-D₁ pair, like the rightmost column of FIG. 4, by repeatedly performing operations for n time units.

In other words, as illustrated in FIG. 4, the in-memory data processing apparatus performs a step of sequentially receiving an instruction set I from the outside; a step of selecting, by a selector set, a data set D to be used for an operation corresponding to the instruction set; a step of performing, by a plurality of PUs, an operation corresponding to the instruction set I and the data set D; and a step of delivering instructions included in the instruction set to the subsequent, adjacent, PU.

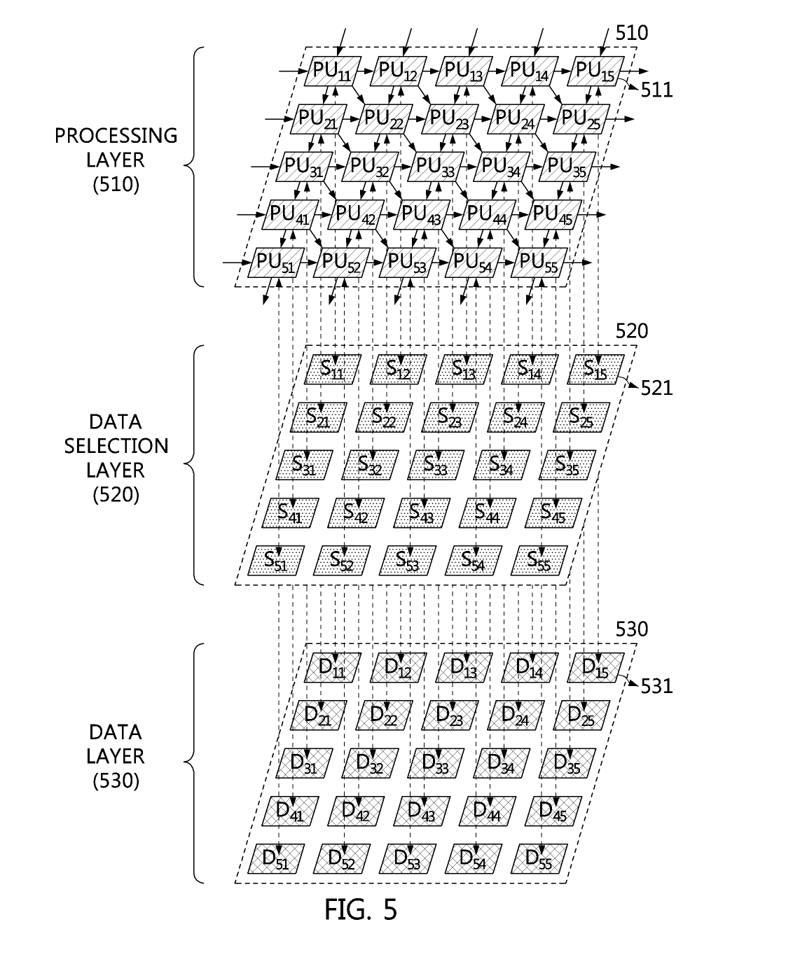

FIG. 5 is an exemplary diagram illustrating the hardware logic structure of an in-memory data processing apparatus according to an embodiment of the present invention.

The structure of the in-memory data processing apparatus according to an embodiment of the present invention may be configured and realized in various types, and as illustrated in FIG. 5, hardware of the in-memory data processing apparatus may be realized using PUs 511, data memories 531, and additional selector units 521.

FIG. 5 illustrates a structure capable of performing a complex operation such as a matrix operation by arraying the PUs 511 two-dimensionally. As illustrated in FIG. 5, upon performing a complex operation, the in-memory data processing apparatus may include selector units for selecting necessary data from among an available data set in order to perform the operation.

As illustrated in FIG. 5, a processing layer 510 has a structure in which a plurality of unit PUs 511 are arrayed two-dimensionally. In addition, each PU 511 delivers an instruction and the processing result of a corresponding PU to an adjacent PU, and sequentially processes the operation.

A data selection layer 520 is located between a processing unit PUₙₘ and a data set Dₙₘ configured with one or more data items, and selects a data set Dₙₘ to be used in PUₙₘ. The selector unit 522 selects data to be used for an operation from among a plurality of operands (i.e. data) in the memory.

In addition, a data layer 530 is configured with physical memory devices.

In FIG. 5, it is described that PU-selector unit-data set configures one unit (i.e. Pₙₘ-Sₙₘ-Dₙₘ pair), but the embodiment is not limited thereto.

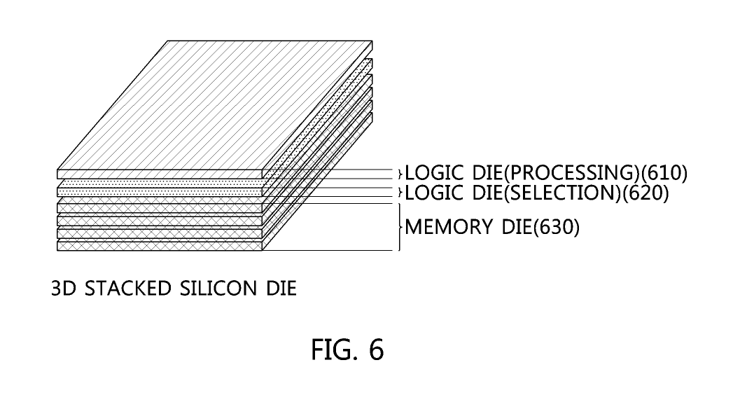

FIG. 6 is an exemplary diagram illustrating the physical structure of an in-memory data processing apparatus according to an embodiment of the present invention.

As illustrated in FIG. 6, the physical hardware structure of the in-memory data processing apparatus may be configured with a processing layer 610, a data selection layer 620, and a data layer 620, which are stacked. In other words, a plurality of silicon dies, on each of which the processing layer 610, the data selection layer 620 and the data layer 630 are realized, are stacked to realize a 3D stacked silicon die type.

However, the logic structure, physical structure, and shape of the data-driven in-memory data processing apparatus according to an embodiment of the present invention are not limited to the examples illustrated in FIGS. 5 and 6.

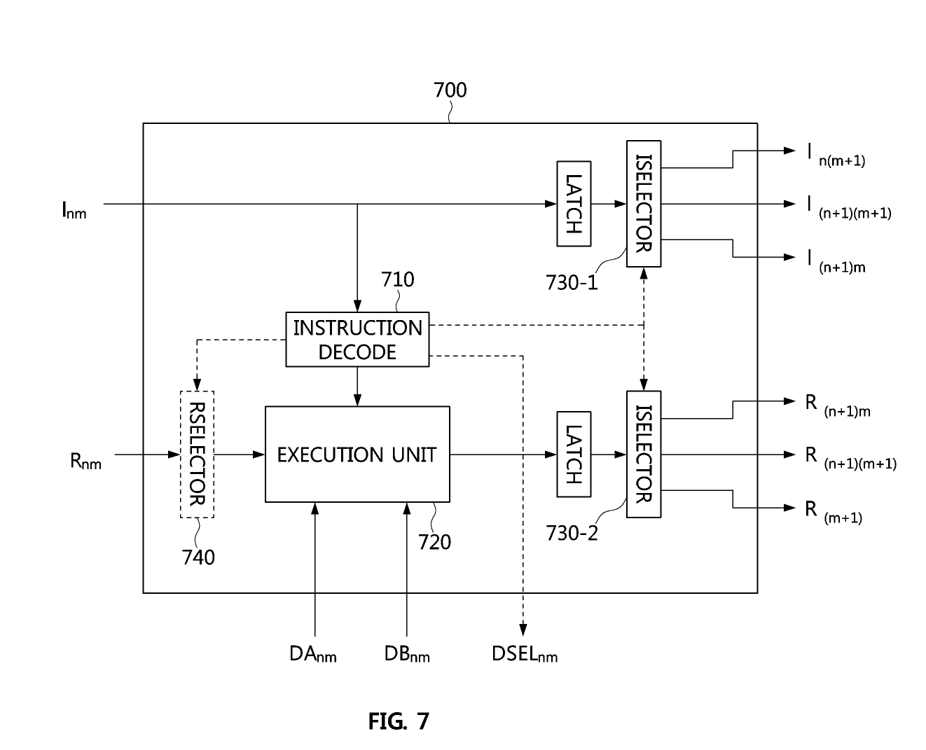

FIG. 7 is a drawing for explaining a processing unit structure according to an embodiment of the present invention.

As illustrated in FIG. 7, an arbitrary processing unit PUₙₘ 700 located in the processing layer receives and uses, as an input, an instruction Iₙₘ input from a preceding PU and an operation result Rₙₘ of the preceding PU. In addition, the processing unit PUₙₘ 700 outputs instructions, In₍ₘ₊₁₎, I₍ₙ₊₁₎₍ₘ₊₁₎, and I₍ₙ₊₁₎ₘ, which are instructions for delivering instructions used in a previous time unit, to any one PU among PUₙ₍ₘ₊₁₎, PU₍ₙ₊₁₎₍ₘ₊₁₎, and PU₍ₙ₊₁₎ₘ, which are subsequent adjacent stages in a 2-dimensional array, and operation results Rₙ₍ₘ₊₁₎, R₍ₙ₊₁₎₍ₘ₊₁₎, and R₍ₙ₊₁₎ₘ.

In addition, the processing unit PUₙₘ 700 outputs a DSELₙₘ signal, which is a signal for selecting data necessary for operation, from the data set Dₙₘ and receives DAₙₘ and DBₙₘ as input operation data.

In addition, the processing unit PUₙₘ 700 internally includes an instruction decoder 710, an internal execution unit 720, an input result selector (RSelector) 740 for selecting an input/output, and output selectors (ISelector) 730-1 and 730-2.

The processing unit PUₙₘ 700 processes data by analyzing an input instruction, specifying the type of operation to be processed, and delivering the type to the execution unit. In addition, the instruction decoder 710 generates a signal for selecting the result of the previous step and a signal for selecting the next step. In addition, an input result selector (RSelector) 740 selects whether to use the result of the previous step, which is input in response to the output of the instruction decoder 710, and the output selectors (ISelector) 730-1 and 730-2 determine the PU to which the instruction and operation result are delivered.

In addition, the instruction decoder 710 generates the DSELₙₘ signal, which is a data selection signal, and receives input operation data DAₙₘ and DBₙₘ through Sₙₘ of the data selection layer.

For convenience of explanation, the PU is described as including the selector unit, but the embodiment is not limited thereto, and the PU may be realized using a separate external selector unit. In addition, when the external selector unit is used separately or the PU is connected one-dimensionally, or if necessary, the ISelectors, the RSelector, and the DSELₙₘ may be selectively omitted.

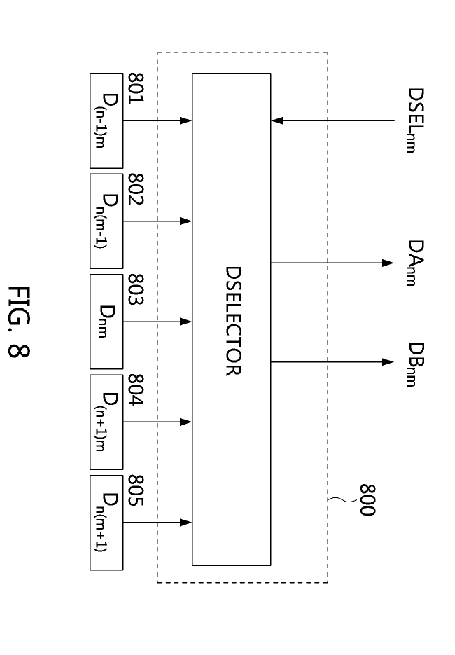

FIG. 8 is a drawing for explaining a selector unit structure according to an embodiment of the present invention.

Like FIG. 8, the selector unit 800 selects and outputs data to be used for operation using the DESLₙₘ signal delivered from the processing unit PUₙₘ. In other words, the selector unit 800 selects data DAₙₘ and DBₙₘ to be used for an operation from among data D₍ₙ₋₁₎ₘ, Dₙ₍ₘ₋₁₎, Dₙₘ, D₍ₙ₊₁₎ₘ, and Dₙ₍ₘ₊₁₎ configuring the data set Dₙₘ using the DSELₙₘ signal. At this point, the type and number of data forming the data set Dₙₘ are not limited to the description made in relation to FIG. 8.

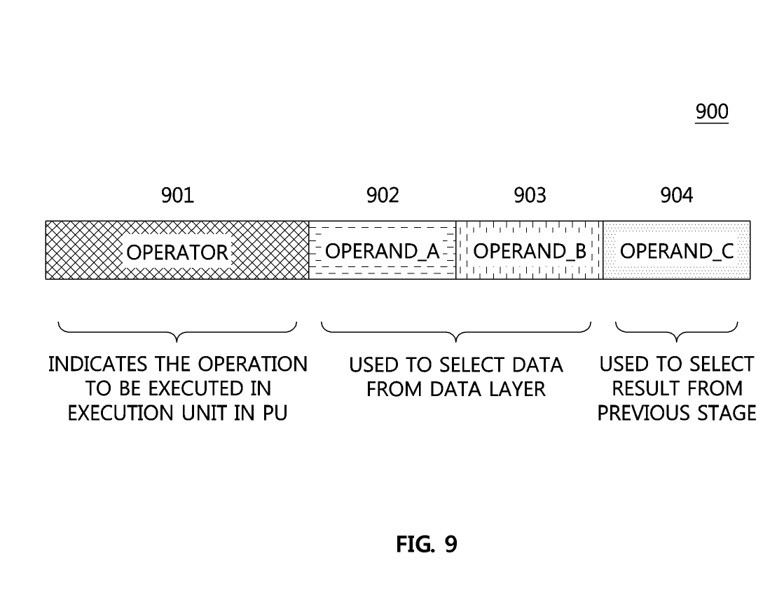

FIG. 9 is a drawing for explaining an instruction set structure according to an embodiment of the present invention.

As illustrated in FIG. 9, an instruction set 900 is configured with one or more operators 901, a plurality of operands OPERAND_A and OPERAND_B 902 and 903, and at least one operation result OPERAND_C 904.

First, the operator 901 means the type of operation to be performed in an execution unit in a PU.

In addition, the first operand 902 and the second operand 903 mean data in memory required by the execution unit. In addition, the first operand 902 and the second operand 903 are used for generating the DSELₙₘ signal for a selector unit.

Finally, the operation result 904 means information about whether the PU uses the output of the previous step and the PU to which the current PU delivers the result. In addition, the operation result 904 may be used to control the RSelector and ISelectors in the PU.

For convenience of explanation, the instruction set structure has been described as the same as FIG. 9, a scheme and a configuration, such as a bit width for each field in the instruction set or bit allocation, are not limited thereto.

In the processing unit and in-memory data processing apparatus and method described above, the configuration and the method of the above-mentioned exemplary embodiments are not limitedly applied. That is, all or some of the respective exemplary embodiments may be selectively combined with each other so that they may be variously modified.

According to the present invention, for data processing, a time delay limitation owing to movement of data stored in external memory to a PU through a bus can be overcome, and a performance degradation attributable to the time delay can be prevented, thereby enabling data processing at a high speed.

In addition, the present invention can reduce unnecessary energy consumption for data processing and can accordingly process large amounts of data with small power consumption.

As described above, in the processing unit and in-memory data processing apparatus and method according to the present invention, the configurations and schemes in the above-described embodiments are not limitedly applied, but some or all of the above embodiments can be selectively combined and configured, whereby various modifications are possible.

As described above, optimal embodiments of the present invention have been disclosed in the drawings and the specification. Although specific terms have been used in the present specification, these are merely intended to describe the present invention and are not intended to limit the meanings thereof or the scope of the present invention described in the accompanying claims. Therefore, those skilled in the art will appreciate that various modifications and other equivalent embodiments are possible from the embodiments. Therefore, the technical scope of the present invention should be defined by the technical spirit of the claims.

What is claimed is:

1. An in-memory data processing apparatus, comprising:
a memory for storing data at a determined location;
a plurality of selector units for selecting a data set to be used for an operation from among the stored data; and
a plurality of processing units for performing the operation using an instruction set sequentially received from an outside and the selected data set.

2. The in-memory data processing apparatus of claim 1, wherein the plurality of processing units are mutually connected in a multi-dimensional array.

3. The in-memory data processing apparatus of claim 1, wherein the data stored in the memory is directly connected to each of the processing units through the selector units.

4. The in-memory data processing apparatus of claim 1, wherein a number of selector units corresponds to a number of the plurality of processing units and the plurality of selector units are mutually connected in a multi-dimensional array.

5. The in-memory data processing apparatus of claim 4, wherein the processing units are respectively paired with the selector units for selecting data to be processed by the processing units.

6. The in-memory data processing apparatus of claim 5, wherein each of the selector units allows each processing unit paired therewith to combine and form a pair with data stored at a specific location in the memory.

7. The in-memory data processing apparatus of claim 6, wherein the processing unit and data pairs are connected in series to be operated by each of the processing units.

8. The in-memory data processing apparatus of claim 7, wherein an input to the processing unit is received from a preceding adjacent processing unit and comprises a previous instruction which correspond to an operation to be performed by the corresponding processing unit and data to be used for the operation, and a previous processing result and the data received from the selector unit corresponding to the processing unit.

9. The in-memory data processing apparatus of claim 8, wherein an output of the processing unit is an instruction that is received and is being performed by the processing unit and a processing result corresponding to the instruction.

10. The in-memory data processing apparatus of claim 9, wherein the processing units uses a common clock or an asynchronous handshaking scheme so as to deliver the instruction and the processing result, which are output from the processing unit, to a subsequent adjacent processing unit.

11. The in-memory data processing apparatus of claim 9, wherein:
the processing unit outputs a data selection signal for requesting selection of data to be used for operation to the selector unit corresponding to the processing unit, and
the selector unit selects some data from among the data set corresponding to the processing unit and transmits the selected data to the processing unit.

12. The in-memory data processing apparatus of claim 1, wherein:
the instruction set is sequentially applied to the processing unit, and
instructions comprised in the instruction set are configured with one or more operator fields, a plurality of operand fields, and one or more operation result fields.

13. A processing unit, comprising:
an instruction decoder for decoding an instruction comprising an operation to be performed and data used for the operation to generate a control signal;
an internal execution unit for operating on the data so as to correspond to the instruction;
an input result selector for determining whether to use a processing result of a preceding processing unit, which has been input, using the control signal; and
an output selector for selecting a subsequent processing unit to which the instruction and a processing result corresponding to the instruction are to be delivered.

14. The processing unit of claim 13, wherein the instruction decoder decodes an instruction set sequentially received from an outside or a previous instruction received from the preceding processing unit, which is adjacent thereto.

15. The processing unit of claim 13, wherein the internal execution unit outputs the instruction that is being performed by the processing unit and the processing result corresponding to the instruction.

16. The processing unit of claim 14, wherein the instruction set is configured with one or more operator fields, a plurality of operand fields, and one or more operation result fields.

17. The processing unit of claim 16, wherein the operator field indicates a type of operation to be executed by the internal execution unit,
the operand field indicates data necessary for operation among a data set, and
the operation result field indicates whether the processing unit performs an operation using the operation result of the preceding processing unit or indicates whether to deliver the operation result of the processing unit to the subsequent processing unit.

18. The processing unit of claim 13, which is embedded in a memory device in which the data is stored.

19. A data processing method performed by an in-memory data processing apparatus, the data processing method comprising:
sequentially receiving an instruction set from an outside;
selecting, by a selector unit, a data set to be used for an operation corresponding to the instruction set from a memory in which data is stored at a determined location; and
performing an operation corresponding to the instruction set and the data set using a plurality of processing units.

20. The data processing method of claim 19, wherein the plurality of processing units are mutually connected in a multi-dimensional array.
